(19) United States
(12) Patent Application Publication
(10) Pub. No.: US 2008/0073069 A1
(43) Pub. Date: Mar. 27, 2008

(54) HEAT SINK

(75) Inventors: JENG-DA WU, Tu-Cheng (TW); CHIH-HANG CHAO, Tu-Cheng (TW); YU-HSU LIN, San Jose, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,777

(22) Filed: Sep. 23, 2006

(51) Int. Cl. H05K 7/20

(52) U.S. Cl. 165/185; 165/80.3; 361/704

(57) ABSTRACT

A heat sink is provided to include a base (10) and a plurality of fins (20) mounted on the base. Each fin includes a heat dissipating portion (21). A plurality of notches (111) is defined in the base. A plurality of tabs (23) is protruded down from a bottom of each heat dissipating portion corresponding to the notches respectively.

### FIELD OF THE INVENTION

The present invention relates to heat sinks, more particularly to a heat sink for dissipating heat from an electronic device.

### DESCRIPTION OF RELATED ART

Computers are continuing to rapidly develop. Electronic devices in computers, such as central processing units (CPUs), generate a lot of heat during normal operation. This can deteriorate their operational stability, and damage associated electronic devices. Thus, the heat must be removed quickly to ensure normal operation of the CPU. A heat sink is often provided on the CPU to remove heat therefrom.

A conventional heat sink usually includes a base and a plurality of parallel fins. The fins are generally integrated with the base. In this conventional heat sink, the fins cannot be removed from the base when the fins are damaged and need to be replaced.

What is needed, therefore, is a heat sink having a plurality of fins removably attached to its base.

### SUMMARY OF THE INVENTION

A heat sink includes a base and a plurality of fins mounted on the base. Each fin includes a heat dissipating portion. A plurality of tabs protrude from a bottom of each heat dissipating portion to be received by corresponding notches defined in the base.

Other advantages and novel features will be drawn from the following detailed description of preferred embodiments with attached drawings, in which:

### BRIEF DESCRIPTION OF THE DRAWINGS

FIG. 1 is an exploded, isometric view of a heat sink in accordance with a preferred embodiment of the present invention, the heat sink including a base and a plurality of fins;

FIG. 2 is an assembled view of FIG. 1; and

FIG. 3 is an exploded, isometric view of a heat sink in accordance with another embodiment of the present invention.

### DETAILED DESCRIPTION OF THE INVENTION

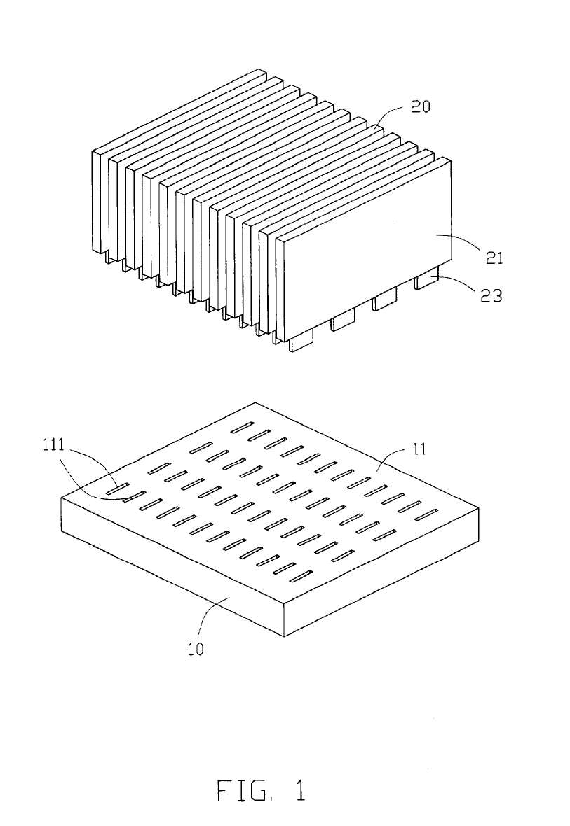

Referring to FIG. 1, a heat sink in accordance with a preferred embodiment of the present invention includes a base 10 and a plurality of fins 20.

The base 10 has a top surface 11 defining a plurality of spaced rectangle notches 111 arrayed in a matrix.

Each fin 20 includes a rectangular heat dissipating portion 21 and a plurality of spaced tabs 23 protruding down from a bottom surface of the heat dissipating portion 21, configured to be engagingly received by corresponding notches 111 of the base 10. In the present embodiment, a thickness of each tab 23 is less than that of the heat dissipating portion 21 but approximately same as the notches 111 allowing a snug fit when received therein.

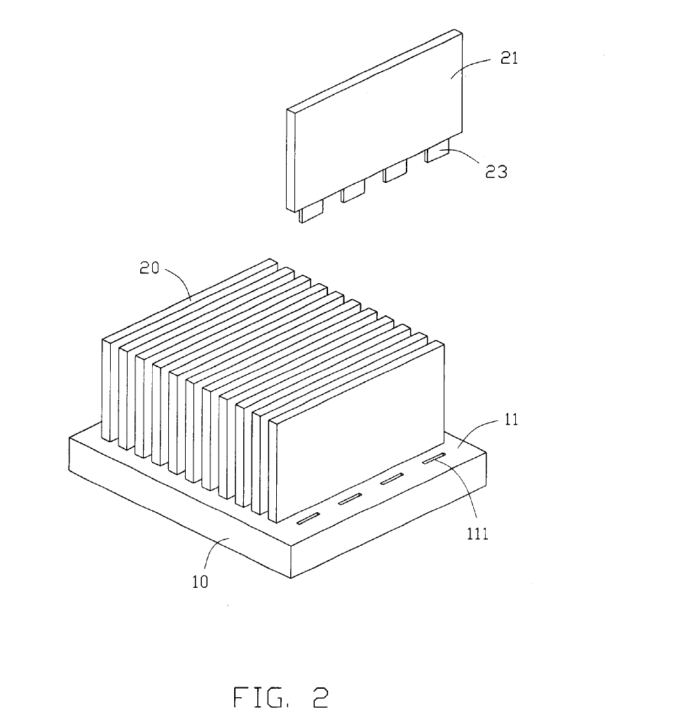

Referring to FIG. 2, in assembly, the tabs 23 on the bottom of each fin 20 are inserted in the corresponding notches 111 until the bottom surfaces of the heat dissipating portions 21 of the fins 20 contact the top surface 11 on the base 10. The tabs 23, received in the notches 111, each have a unitary thickness along length and height directions thereof.

After the base 10 and the fins 20 are assembled together, the distance between two adjacent fins 20 is less than the distance between two corresponding groups of the notches 111 in the base 10.

The bottom surface of the base 10 is tightly contacted with an electronic device, for absorbing heat from the electronic device, and conducting heat to the heat dissipating portions 21 through the tabs 23.

In the preferred embodiment of the present invention, the fins 20 are removably attached to the base 10, allowing ease of replacement should any of the fins 20 become damaged.

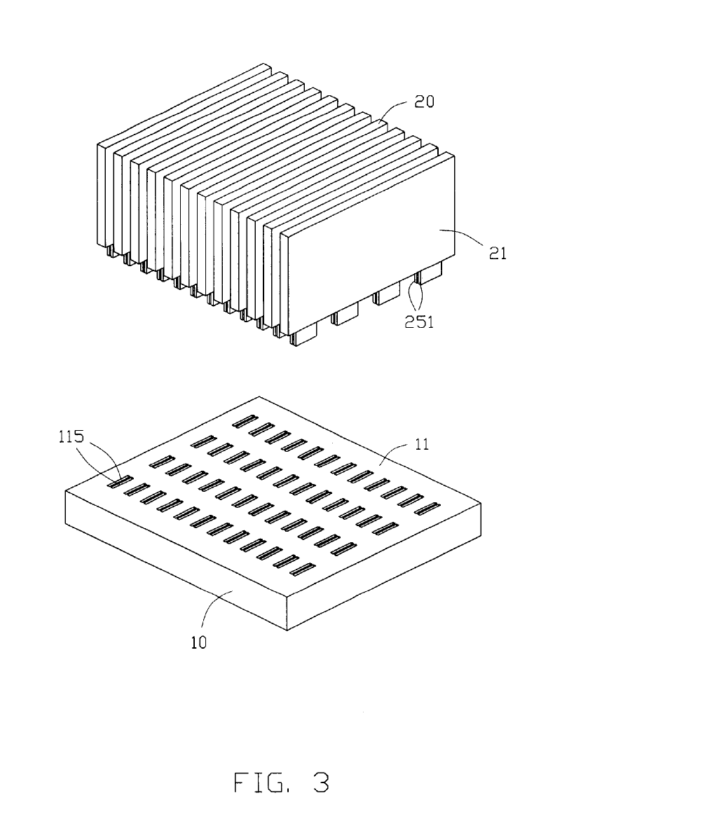

Referring to FIG. 3, another preferred embodiment of the present invention similar to the first preferred embodiment is shown. Differences in the embodiment being that notches 115 are configured for receiving pairs of tabs 251. The tabs 251 protrude in spaced pairs from the bottom surface of the heat dissipating portion 21 of each fin 20. The tabs 251 are so spaced to slightly and resiliently deform when inserted in the corresponding notches 115, thus ensuring a snug fit to stably hold the fins 20 in place.

In other embodiments, the heat dissipating portions 21 can be other shapes. The fins can also be replaced by a plurality of fins having small heat dissipating portions 21. The notches 111, 115 in the base 10 can be other shapes and the tabs 23, 251 on the fins 20 can be corresponding other shapes.

Because the heat sink of the present invention has individual fins 20 and the base 10, in the process of production, the fins 20 may be comparatively thin, improving performance in dissipating heat. When some of the fins are damaged and needed to be replaced the fins 20 are easily replaced since the fins 20 are removably attached with the base 10.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink comprising:
a base with a plurality of notches defined therein; and
a plurality of fins parallel to each other, each fin having a heat dissipating portion and a plurality of tabs protruding down from the heat dissipating portion, the tabs of the fins being removably received into the notches of the base so that the fins are detachably secured on the base.

2. The heat sink as described in claim 1, wherein the thickness of the tab is less than that of the heat dissipating portion.

3. The heat sink as described in claim 1, wherein a distance between two adjacent fins is less than the distance between two corresponding groups of the notches in which the tabs of said two adjacent fins are received.

4. The heat sink as described in claim 1, wherein a bottom surface of the heat dissipating portion which the tabs protruding therefrom contacts with a top surface of the base.

5. The heat sink as described in claim 4, wherein the tabs of each of the fins are arranged on the bottom surface of the heat dissipating portion in pairs, and the notches of the base are correspondingly arranged in pairs.

6. The heat sink as described in claim 4, wherein the tab is inserted in the corresponding notch in a direction perpendicular to the top surface of the base.

7. A heat sink comprising:
a base having a top surface; and
a plurality of parallel fins secured on the base and having a step contacting with the top surface of the base;
wherein the fins are removable from the base.

8. The heat sink as described in claim 7, wherein each fin comprises a heat dissipating portion and a plurality of tabs protruding down from a bottom surface of the heat dissipating portion, and a plurality of notches is defined in the base for releaseably receiving the tabs of the fins.

9. The heat sink as described in claim 8, wherein a thickness of the tab is less than that of the heat dissipating portion.

10. The heat sink as described in claim 8, wherein a distance between two adjacent fins is less than between two corresponding notches of the base.

11. The heat sink as described in claim 8, wherein the bottom of the heat dissipating portion is in contact with the top surface on the base.

12. The heat sink as described in claim 8, wherein the tab is tightly contacted with the corresponding notch.

13. A heat sink comprising:
a base defining a plurality of notches sunk from a top surface thereof; and
a plurality of fins each having a heat dissipating portion and a plurality of spaced tabs extending down from a bottom surface of the heat dissipating portion, the tabs of the fins being removably engaged in the notches of the base with the bottom surface of the heat dissipating portions contacting with the top surface of the base so that the fins are detachably secured on the base.

14. The heat sink as claimed in claim 13, wherein the thickness of the tab is less than that of the heat dissipating portion and a distance between two adjacent fins is less than the distance between two corresponding groups of the notches in which the tabs of said two adjacent fins are received.

15. The heat sink as claimed in claim 13, wherein the heat dissipating portion and the plurality of spaced tabs of each fin are integrally formed.

16. The heat sink as claimed in claim 13, wherein the tabs of each of the fins are arranged on the bottom surface of the heat dissipating portion in pairs facing to each other, and the notches of the base are correspondingly arranged in pairs.

17. The heat sink as claimed in claim 13, wherein the tab has a unitary thickness in the corresponding notch along length and height directions thereof.
